(19) United States
(12) Patent Application Publication
(10) Pub. No.: US 2009/0286435 A1
(43) Pub. Date: Nov. 19, 2009

(54) Method for Producing, and a Substrate with, a Surface with Specific Characteristics

(76) Inventors: Jas Pal S. Badyal, County Durham (GB); Declan Oliver H. Teare, Old Elvet (GB); Wayne C. Schofield, Chester (GB)

Correspondence Address: CLARK & ELBING LLP, 101 FEDERAL STREET, BOSTON, MA, 02110, US

(21) Appl. No.: 11/918,390

(22) PCT Filed: Apr. 12, 2006
(86) PCT No.: PCT/GB2006/001329

§ 371 Date: Jun. 3, 2009

(30) Foreign Application Priority Data
Apr. 14, 2005 (GB) 0507537.9

(51) Int. Cl. B32B 9/04; C23C 14/34; B05D 1/00; B32B 27/06; B32B 17/06; B32B 15/04; B32B 29/00; B32B 21/04

(52) U.S. Cl. 442/59; 204/192.15; 427/569; 428/422; 428/426; 428/457; 428/500; 428/532; 428/537.1; 428/537.5; 428/689; 428/704

(57) ABSTRACT

The invention relates to a method of rendering the surface of a substrate, or at least part of the substrate, to have increased protein resistance. This is achieved by applying an n-substituted glyconic derivative onto the surface of the substrate, or areas or domains of the substrate surface, to allow the pattern resistance to be changed in those areas where the material is applied. In one embodiment the deposition is performed in or in conjunction with a plasma.

The invention to which this application relates is a method of depositing a material onto a substrate to form a surface having specific characteristics and particularly, although not necessarily exclusively, the development of a surface layer which is protein-resistant on at least portions thereon.

Although the following description refers almost exclusively to use of an n-substituted glycine derivative to coat a substrate surface, it will be appreciated by persons skilled in the art that other substances can be utilised to increase the protein resistance of a surface.

The forces which are understood to govern protein adsorption onto a solid surface comprise hydrogen bonding, hydrophobic- and electrostatic- interactions. Hydrogen bonds tend to form between polar groups contained in the protein and which are present on the surface. Hydrophobic forces arise due to the formation of a water depletion zone at the interface between hydrophobic regions on a protein molecule and a hydrophobic substrate, whilst electrostatic interactions are associated with solvated charged groups on the protein surface and the solid substrate. Once adsorbed onto a surface, a protein may either stay in its natural conformation, or denature (unfold), and such binding can be irreversible. For instance, in the case of hydrophobic substrates, proteins usually unfold in order to maximize interactions with the surface.

Since the late 1980s there has been a growing interest in surfaces and coatings which resist this phenomena which is called bio-adhesion (i.e. proteins, cells, and bacteria). The most widely studied systems for minimising bio adhesion have been based upon polyethylene oxide (PEO)/polyethylene glycol (PEG), phospholipids, polysacchatides, and polyacrylamides. As a general rule, surfaces which minimize protein adsorption prove to be resistant towards cell attachment and tissue culture growth.

PEO/PEG surfaces are considered to be the benchmark performers for minimizing protein adhesion. The non-fouling character of PEO surfaces is attributed to the very high levels of polymer chain hydration as well as the conformational flexibility of the polymer. A number of methods exist for making PEO surfaces; these include: gold-, silicon-, silica-, and diamond-based self-assembled monolayers (SAMs), physisorption, chemisorption, surface initiated polymerization, plasma initiated grafting, covalent grafting onto a plasma polymer, and plasma polymerization. A PEO-mimicking thiol-functionalized polyester with ether side chains SAM on gold has also been shown to display minimal protein adsorption characteristics.

However, many of these systems have intrinsic disadvantages: PEO suffers from a susceptibility towards oxidative degradation and chain cleavage in aqueous environments (PEO coatings can degrade and lose their bio-inertness after several days of immersion in buffer). Alkanethiol-gold-based SAMs (which comprise the majority of systems studied so far), such as alkanethiol-terminated gold SAMs of sarcosine based polypeptides, have been shown to exhibit good protein-resistant properties, but SAM systems are known to suffer from being substrate-specific and tend to be unstable as a consequence of their thiolate groups (Au-SR) being susceptible towards oxidation and desorption from the gold surface, leading to a complete loss of the protein-resistant properties.

Phospholipids are another extensively studied class of molecules capable of rendering surfaces protein-resistant. These biomimetic surfaces resemble the outer lipid membrane surface of erythrocytes, and as such they are non-thrombogenic. In particular, phosphorylcholine (the head group of lecithin) based surfaces have been shown to improve biocompatibility. The protein resistance behaviour of phosphorylcholine surfaces can be attributed to the very high levels of hydration of the zwittetionic headgroup; these positive and negative charges render the surface neutral over a large pH range. This hydration layer ensures that proteins which come into contact with the surface do so reversibly and without deformation.

Many of the methods employed to produce phosphorylcholine surfaces rely on the ability of these amphiphilic molecules to self-assemble as planar supported lipid bilayers, (or multilayers). This has been achieved by spin coating, Langmuit-Blodgett deposition, and liposome adsorption. However, a major drawback encountered with most of these systems is that they are reliant upon weak van der Waals interactions (the phosphorylcholine molecules themselves being only weakly associated with each other and to the underlying substrate, thereby compromising the overall bulk physical properties of the material). Attempts aimed at improving the binding of phosphorylcholine-based films have included grafting to plasma irradiated surfaces, forming SAMs of phosphorylcholine terminated alkanethiols onto gold, cross-linking the phosphorylcholine chains via diene groups in the alkyl chains, and copolymerizing phosphorylcholine-methacrylates with other monomers.

Saccharide groups are also known for their protein-resistant behaviour. In a similar manner to PEO/PEG and phospholipids, these hydrophilic surfaces are highly hydrated and thus render the substrate protein-resistant. For instance, dextran is reported to be protein-resistant, and limits the adhesion and spreading of cells, although absolute protein rejection is not observed. Alkanethiol-based saccharide SAMs which have displayed protein resistance comparable to PEO, include methylated sorbitol and mannitol. The latter is capable of sustaining protein-resistant behaviour for much longer periods of time compared to PEO based SAMs (thus overcoming one of the principal disadvantages of PEO).

Polyacrylamides are another category of protein-resistant surface. In particular, the thermoresponsive polymer poly(n-isopropylacrylamide) behaves as a protein-resistant material below its lower critical solution temperature (LCST), and switches to being protein-adsorbent above its LCST. A main disadvantage in this case is that it absorbs protein at body temperature.

Other surfaces that have been found to exhibit protein resistance include tripropylsulphoxide terminated alkanethiol SAMs and elastin-like polypeptide coatings. Lately, there has been an interest in various alternative protein-resistant alkanethiol-gold SAMs based on kosmotropes (molecules that exclude themselves from the protein-water interface) such as polyols, betaine, taurine, trimethylamine-N-oxide, dimethyl acetamide, dimethyl sulphoxide, and hexamethylphosphoramide.

Finally, there is an alternative strategy where adsorption of serum albumin onto a surface can lead to the suppression of protein adsorption. However, this method is not particularly robust, and adsorbed proteins are vulnerable to eventual displacement by more surface active proteins due to the Vroman effect.

The aim of the present invention is to provide a method of producing a protein-resistant surface which overcomes the above issues.

In a first aspect of the invention, there is provided a method of coating a surface with a material, via one or more application steps, to increase the protein resistance of at least part of the surface, wherein said material is an n-substituted glycine derivative.

In one embodiment the n-substituted glycine derivative includes one or more unsaturated polymerizable functional groups. Typically the group is any or any combination of vinyl, styrene, acrylate, methacrylate, acrylamide, and/or the like. In a preferred embodiment the n-substituted glycine derivative includes an acrylamide group.

In a preferred embodiment the n-substituted glycine derivative is a methyl ester of glycine.

In one embodiment the n-substituted glycine derivative is or includes n-acryloylsarcosine methyl ester.

In accordance with the invention the instability of the SAM system is thus overcome by adopting an acrylamide form of sarcosine for polymerization to produce a protein-resistant film.

In an alternative embodiment the n-substituted glycine derivative is any or any combination of n-methyl-n-2-propenyl methyl ester, acryloylsarcosine methyl ester, N-methoxyethylglycine oligomers, sarcosine-based monomers, and/or other n-substituted glycine derivatives.

In an alternative embodiment the n-substituted glycine derivative is polymerized in combination with other polymerizable monomers to form n-substituted glycine copolymers. Typically, monomers for co-polymerization include any or any combination of vinyls, styrenes, acrylates, acrylamides, and/or the like.

In one embodiment the application method includes pulsed plasmachemical deposition. In another embodiment the application includes low-power continuous-wave plasma deposition.

Typically pulsed plasmachemical deposition constitutes the generation of active sites at the surface and in the electrical discharge during a duty cycle on-period, followed by conventional polymerization reaction pathways proceeding during an extinction period. Typically the active sites are predominantly radicals.

Typically the duty cycle on-period lasts 1-100 microseconds. Typically the extinction period lasts 1-20 milliseconds.

Typically the application steps are solventless and/or substrate independent.

In an alternative embodiment the application steps include any or any combination of grafting by pre-irradiation of a surface with ionizing radiation or plasma, grafting by surface polymerization from an initiator layer, by free radical polymerization, atom transfer free radical polymerization, iniferter polymerization, ionic polymerization, and/or photopolymerization.

In an alternative embodiment the application method includes any or any combination of the steps of surface physisorption or chemisorption of pre-formed n-substituted glycine derivative oligomers or polymers onto a solid surface.

Typically the plasma operates at low, sub-atmospheric or atmospheric pressure. In one embodiment the n-substituted glycine derivative is introduced into the plasma as a vapour or an atomised spray of liquid droplets. In one embodiment the monomer is introduced into the pulsed plasma deposition apparatus continuously, or in a pulsed manner by way of, for example, a gas pulsing valve.

In one embodiment the substrate to which the protein resistant coating is applied is located substantially inside the pulsed plasma during coating deposition. Alternatively the substrate may be located outside of the pulsed plasma, thus avoiding excessive damage to the substrate or growing coating.

Typically the n-substituted glycine derivative is directly excited within the plasma discharge. Alternatively, remote plasma deposition methods may be used, wherein the monomer enters the deposition apparatus substantially downstream of the pulsed plasma, thus reducing the potentially harmful effects of bombardment by short-lived, high energy species such as ions.

In one embodiment the plasma comprises the n-substituted glycine derivative alone, substantially in the absence of other compounds. Plasmas consisting of n-substituted glycine derivative alone may be achieved by first evacuating the reactor vessel as far as possible, and then purging the reactor vessel with the n-substituted glycine derivative for a period sufficient to ensure that the vessel is substantially free of other gases. Typically the temperature in the plasma chamber is sufficiently high to allow sufficient monomer in gaseous phase to enter the plasma chamber. This will depend upon the monomer and conveniently ambient temperature will be employed. However, elevated temperatures for example from 25 to 250° C. may be required in some cases.

In alternative embodiments of the invention, materials additional to the n-substituted glycine derivative are present within the plasma deposition apparatus. The additional materials may be introduced into the coating deposition apparatus continuously or in a pulsed manner by way of, for example, a gas pulsing valve. Typically said additive materials are inert and act as buffers without any of their atomic structure being incorporated into the growing plasma polymer. Typically said additive materials are noble gases. A buffer of this type may be necessary to maintain a required process pressure and/or sustain the plasma discharge. For example, the operation of atmospheric pressure glow discharge (APGD) plasmas often requires large quantities of helium. This helium diluent maintains the plasma by means of a Penning Ionisation mechanism without becoming incorporated within the deposited coating.

In alternative embodiments of the invention, the additive materials may be other monomers such that the resultant coatings comprise copolymers. Suitable monomers for use within the method of the invention include organic, inorganic, organo-silicon and organo-metallic monomers.

In one embodiment the method also improves resistance towards cell adhesion, bacteria adhesion, and/or enzyme degradation. The method could be employed for use in bio-micro electromechanical systems and for coating other biomaterial surfaces where an immune response is not desired.

In a further aspect of the invention, there is provided a method of applying a material to a substrate to increase the protein resistance of at least part of the substrate surface formed by the applied material, wherein said method includes the step of applying the material using a pulsed plasmachemical deposition technique.

In one embodiment the material is an n-substituted glycine derivative.

In a further aspect of the invention, there is provided a method of applying a material to a substrate, via one or more application steps, to increase the protein resistance of the surface, wherein said material which is applied is a poly(n-acryloylsarcosine methyl ester).

Typically the method results in a product wholly coated in a protein resistant polymer coating.

Alternatively the protein resistant polymer coating is only applied to selected surface areas or domains. Typically the restriction of the protein resistant polymer coating to specific surface domains is achieved by limiting the means of coating production of the method to said specific surface domains. In one embodiment the restriction is achieved by plasma depositing the coating through a mask or template. This produces a surface exhibiting regions covered with protein resistant polymer juxtaposed with regions that exhibit no protein resistant polymer.

An alternative means of restricting the protein resistant behaviour of the polymer coating to specific surface domains comprises: depositing the protein resistant polymer over the entire surface of the sample or article, before rendering selected areas of it incapable of protein resistance. The spatially selective removal/damage of the protein resistant polymer material which has been applied may be achieved using electron beam etching and/or exposure to ultraviolet irradiation through a mask. The pattern of non-transmitting material possessed by the mask is hence transferred to areas of protein resistance.

In one embodiment the material restricted to specific surface domains is an n-substituted glycine derivative.

In a further aspect of the invention there is provided a substrate having an outer surface formed at least partially of an n-substituted glycine derivative.

In one embodiment the substrate has a layer of n-substituted glycine derivative applied thereto to form an outer surface thereof.

In one embodiment the substrate includes a protein resistant coating obtained by a process as described above, said substrate including any solid, particulate, or porous substrate or finished article, typically consisting of any or any combination of materials such as, but not limited to, woven or non-woven fibres, natural fibres, synthetic fibres, metal, glass, ceramics, semiconductors, cellulosic materials, paper, wood, or polymers such as polytetrafluoroethylene, polythene or polystyrene. In a particular embodiment, the surface comprises a polymeric support material, capable of use in biochemical analysis or in vitro.

In a further aspect of the invention there is provided a method of forming a protein resistant outer surface of a substrate, said method including the step of applying an n-substituted glycine derivative onto at least part of a surface of said substrate using a pulsed plasmachemical deposition procedure.

A specific embodiment of the invention is now described hereinbelow wherein;

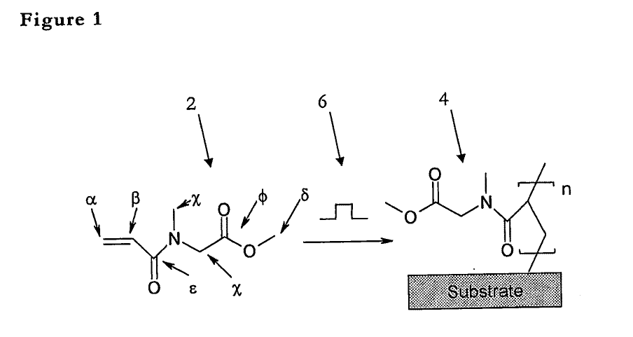

FIG. 1 illustrates the polymerization of n-acryloylsarcosine methyl ester to form a surface coating in accordance with one embodiment of the invention.

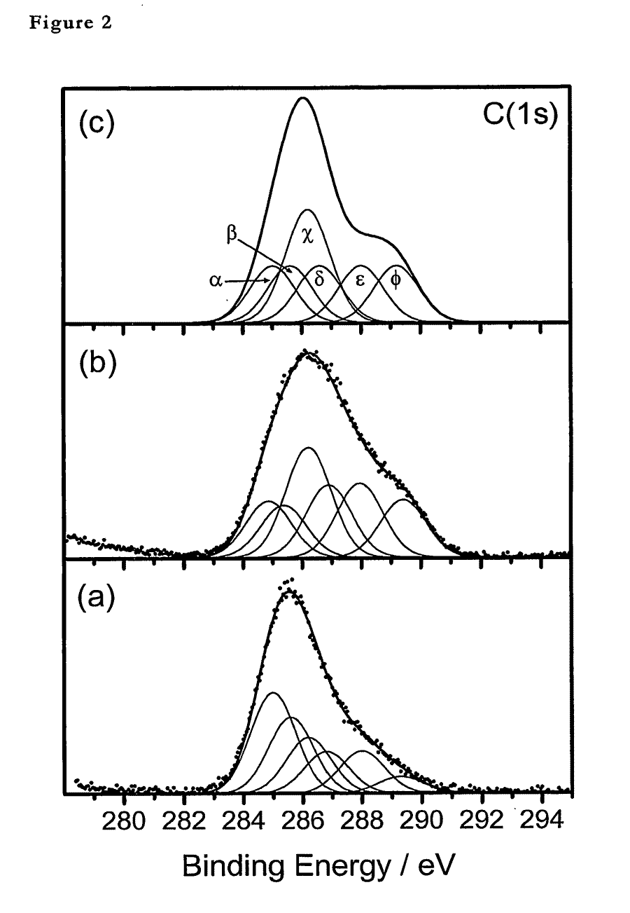

FIG. 2 illustrates XPS C(1s) envelopes of poly(n-acryloylsarcosine methyl ester): (a) 30 W continuous wave plasma deposited; (b) pulsed plasma deposited (Pₚ=30 W, t_{ON}=20 μs, t_{off}=5 ms); and (c) theoretically predicted.

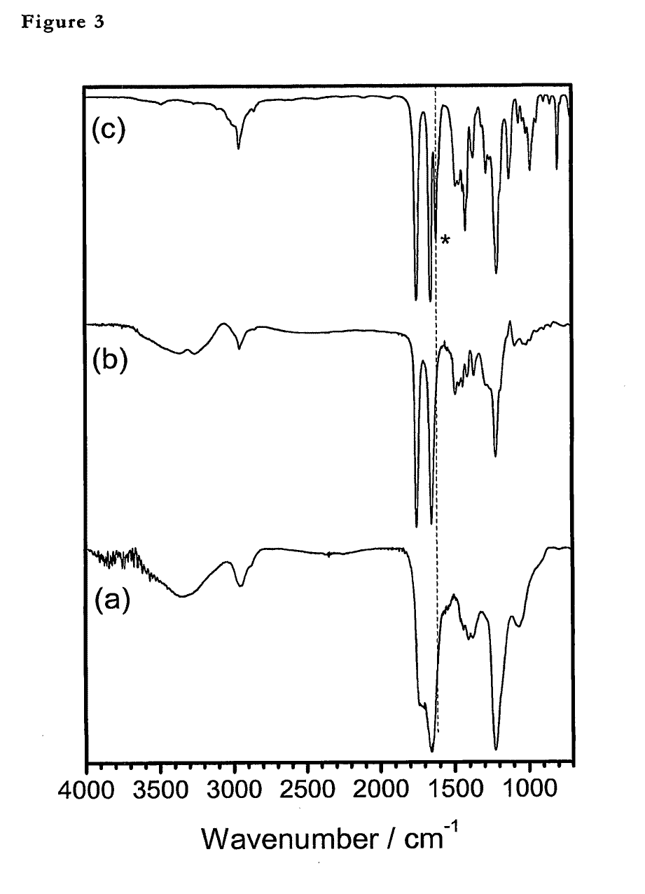

FIG. 3 illustrates FTIR spectra of: (a) 30 W continuous wave plasma polymerized n-acryloylsarcosine methyl ester; (b) pulsed plasma (Pₚ=30 W, t_{ON}=20 μs, t_{off}=5 ms) polymerized n-acryloylsarcosine methyl ester; and (c) n-acryloylsarcosine methyl ester monomer.

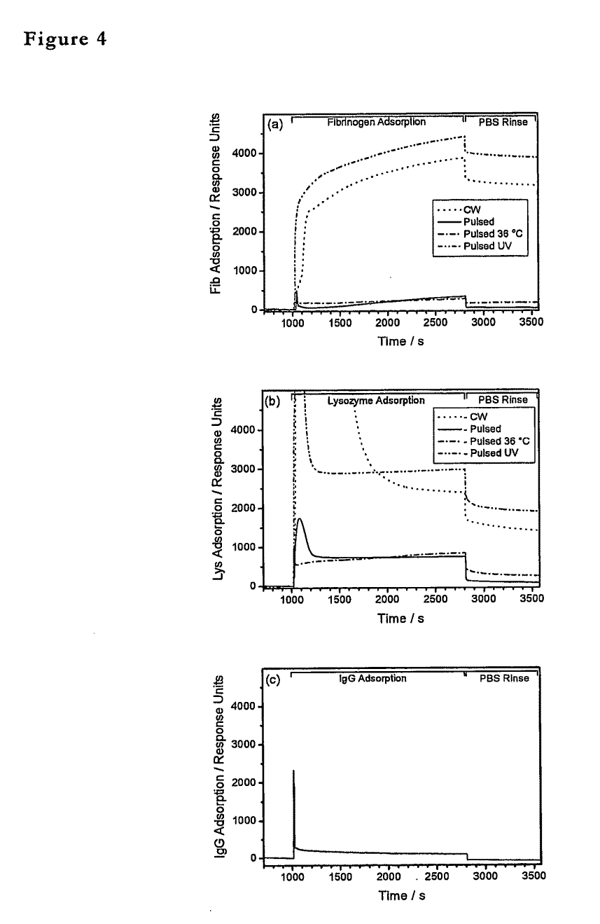

FIG. 4 illustrates SPR of protein adsorption onto plasma polymerized n-acryloylsarcosine methyl ester films: (a) fibrinogen; (b) lysozyme; and (c) Alexa-fluor 633 IgG. (Pₚ=30 W (CW and pulsed), tₒₙ=20 μs, and t_{off}=5 ms).

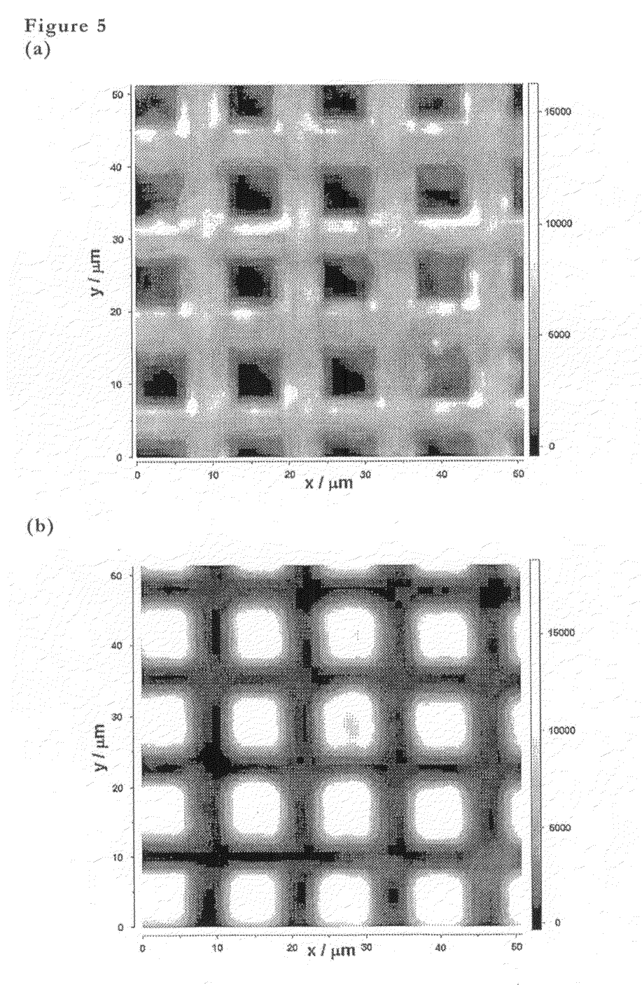

FIG. 5 illustrates fluorescence micrographs of pulsed plasma deposited poly(n-acryloylsarcosine methyl ester) arrays following immersion in Alexa-fluor 633 IgG/PBS solution: (a) embossed pattern (negative image); and (b) UV exposed pattern (positive image). (Pₚ=30 W, t_{ON}=20 μs, and t_{off}=5 ms).

FIG. 6 illustrates fluorescent microscope images of a micro-spotted array produced on NASME pulsed plasma polymer layer: (a) Protein Probe II; (b) Protein Probe IV;

FIG. 7 illustrates fluorescent microscope images of a micro-spotted array produced on NASME pulsed plasma polymer layer: (a) Protein Probe I subsequently exposed to Probe II; (b) Protein Probe III subsequently exposed to probe IV; and

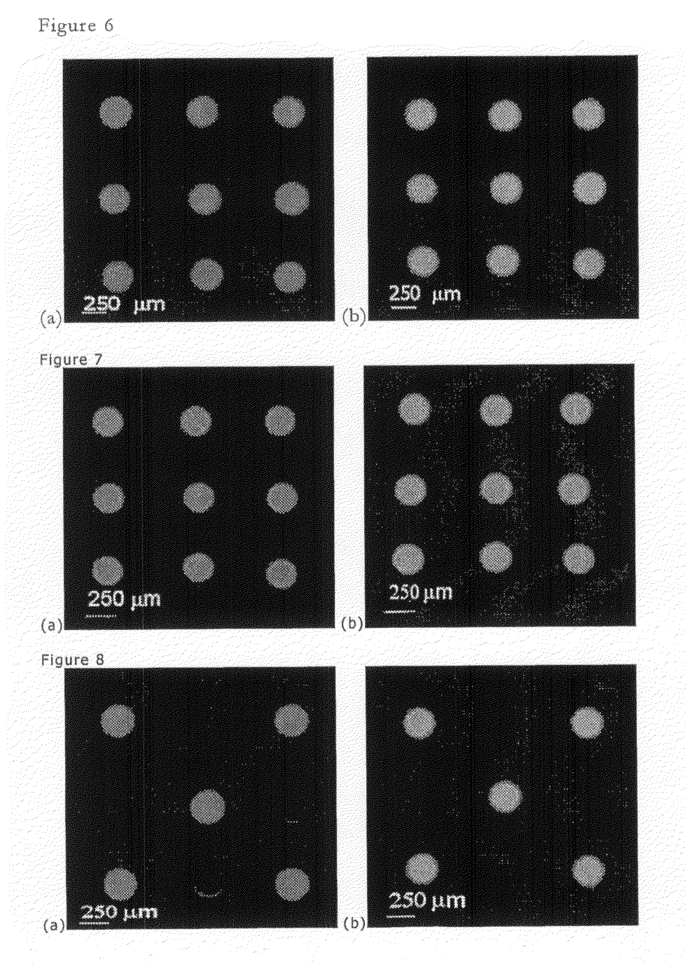

FIG. 8 illustrates fluorescent microscope image of a micro-spotted array produced on NASME pulsed plasma polymer layer: (a) alternating microarray pattern of Protein Probe I and III subsequently exposed to probe II; (b) alternating microarray pattern of Protein Probe I and III subsequently exposed to protein Iv.

With reference to FIG. 1, there is illustrated a method in accordance with one embodiment of the invention in which a pulsed plasma polymerization 6 of n-acryloylsarcosine methyl ester (NASME) 2 is performed to form a polymerized surface coating 4 on a substrate.

Specific method parameters and experimental details are set out below;

N-acryloylsarcosine methyl ester (97%, Lancaster) monomer 2 was loaded into a sealable glass tube and further purified using multiple freeze-pump-thaw cycles. Plasma polymerization 6 was carried out in a cylindrical glass reactor (4.5 cm diameter, 460 cm³ volume, 2×10⁻³ mbar base pressure, and 1.4×10⁻⁹ mol s⁻¹ leak rate), surrounded by a copper coil (4 mm diameter, 10 turns, located 15 cm away from the precursor inlet) and connected to a 13.56 MHz radio frequency (RF) power supply via an L-C matching network. The reactor was located inside a temperature controlled oven and a Faraday cage. A 30 L min⁻¹ rotary pump attached to a liquid nitrogen cold trap was used to evacuate the plasma chamber. System pressure was monitored with a Pitani gauge. All fittings were grease free. During pulsed plasma deposition 6, the RF power source was triggered by a signal generator and the pulse shape monitored with an oscilloscope. Prior to each experiment, the apparatus was scrubbed with detergent, rinsed with propan-2-ol, and oven dried. Further cleaning entailed running a continuous wave air plasma at 0.2 mbar pressure and 40 W power for 20 min. Next, silicon wafers, gold chips, or cut polystyrene squares (15 mm×15 mm) were inserted into the reactor and the system pumped down to base pressure. A continuous flow of n-acryloylsarcosine methyl ester vapour was introduced into the chamber at a pressure of 0.1 mbar and 40° C. temperature for 5 min prior to plasma ignition. The optimum pulsed plasma duty cycle corresponded to 30 W peak power (Pₚ) continuous wave bursts lasting 20 μs (tₒₙ) followed by an off-period (t_{off}) set to 5 ms. Once deposition was completed, the RF power was switched off, and the monomer allowed to continue to purge through the system for a further 5 min prior to evacuating to base pressure and venting to atmosphere.

A spectrophotometer (nkd-6000, Aquila Instruments Ltd.) was used to measure plasma polymer film 4 thickness and deposition rate. The obtained transmittance-reflectance curves (350-1000 nm wavelength range) were fitted to a Cauchy model using a modified Levenberg-Marquardt algorithm.

Contact angle analysis of the plasma deposited n-acryloylsarcosine methyl ester films was carried out with a video capture system (ASE Products, model VCA2500XE) using 2.0 μl droplets of deionized water.

X-ray photoelectron spectroscopy (XPS) was undertaken using an electron spectrometer (VG ESCALAB MK II) equipped with a non-monochromated Mg Kα X-ray source (1253.6 eV) and a concentric hemispherical analyzer. Photo-emitted electrons were collected at a take-off angle of 30° from the substrate normal, with electron detection in the constant analyzer energy mode (CAE, pass energy=20 eV). The XPS spectra were charge referenced to the C(1s) peak at 285.0 eV and fitted with a linear background and equal full-width-at-half-maximum (FWHM) Gaussian components using Marquardt minimization computer software. Instrument sensitivity (multiplication) factors derived from chemical standards were taken as being C(1s): O(1s): N(1s)=1.00: 0.36: 0.57.

The stoichiometry of the plasma deposited poly(n-acryloylsarcosine methyl ester) films was determined by XPS, as indicated in Table 1.

TABLE 1
XPS elemental analysis and water contact angles for plasma
deposited poly(n-acryloylsarcosine methyl ester).

| | XPS | | | Contact |
|---|---|---|---|---|
| Conditions | % C | % N | % O | angle/° |
| Continuous Wave | 72 ± 0.6 | 9 ± 0.1 | 19 ± 0.5 | 41 ± 1.7 |
| Pulsed | 66 ± 0.5 | 9 ± 0.1 | 25 ± 0.6 | 44 ± 0.9 |
| Theoretical | 64 | 9 | 27 | N/A |

(Pₚ = 30 W (CW and pulsed), tₒₙ = 20 μs, and t_{off} = 5 ms).

With reference to FIGS. 1-2, pulsing the plasma at a duty cycle of Pₚ=30 W, tₒₙ=20 μs, and t_{off}=5 ms produced films most resembling the theoretically predicted structure. The absence of any Si(2p) XPS signal from the underlying silicon or gold substrates verified pinhole-free film thicknesses exceeding the XPS sampling depth (2-5 nm)ⁱ.

The XPS C(1s) envelope can be fitted to 6 carbon environments: hydrocarbon (CₓH_{y}=285.0 eV, α), carbon adjacent to a carbonyl group (C—C═O=285.7 eV, β), carbon attached to nitrogen (C—N=286.2 eV, χ), carbon attached to oxygen (C—O=286.6 eV, δ), carbon attached to nitrogen and oxygen (N—C═O=288 eV, ε), and carbon attached to two oxygens (O—C═O=289.3 eV, φ). 30 W continuous wave plasma deposited n-acryloylsarcosine methyl ester films display a high level of disruption of monomer structure as evident from the elemental composition and the distribution of C(1s) components, as shown in Table 1 and FIG. 2. Much better structural retention was achieved during low duty cycle pulsed plasma deposition

With reference to FIG. 3, structural retention for the pulsed plasma deposited poly(n-acryloylsarcosine methyl ester) films was also authenticated by infrared spectroscopy. Surface infrared spectroscopy of plasma polymer coated gold slides was performed using an FTIR spectrometer (Perkin Elmer, model Spectrum One) equipped with a liquid nitrogen cooled MCT detector operating at 4 cm⁻¹ resolution over the 700-4000 cm⁻¹ range. A reflection absorption accessory (RAIRS, Specac) and a I(RS-5 p-polarizer were fitted to the instrument, with the reflection angle set to 80°.

Characteristic absorption bands include 1749 cm⁻¹ (ester carbonyl), 1653 cm⁻¹ (amide I), and 1212 cm⁻¹ (ester C—O). The carbon-carbon double bond absorption at 1615 cm⁻¹ (dashed line marked with *) associated with the monomer is not present in any of the plasma deposited films, thus indicating complete polymerization of the precursor. 30 W continuous wave plasma deposition conditions yielded broad infrared absorption features, which can be taken as being symptomatic of a loss of monomer structural integrity. The low duty cycle pulsed plasma deposited film (Pₚ=30 W, tₒₙ=20 μs, and t_{off}=5 ms) displays much better resolved absorption bands matching those seen for the monomer (apart from the polymerizable carbon-carbon double bond stretch at 1615 cm⁻¹), thereby confirming a high degree of structural retention.

Referring to FIG. 4, SPR analysis of fibrinogen and lysozyme adsorption onto 25 nm thick pulsed plasma deposited poly(n-acryloylsarcosine methyl ester) films (Pₚ=30 W, tₒₙ=20 μs, and t_{off}=5 ms) displayed excellent resistance towards protein adsorption.

Surface plasmon resonance (SPR) protein adsorption studies entailed plasma deposition of 25 nm thick poly(n-acryloylsarcosine methyl ester) films onto a gold sensor chip (Biacore) and monitoring protein adsorption using a biosensor SPR system (Biacore 1000 upgrade). Fibrinogen (from bovine plasma, Sigma) and lysozyme (egg white, Sigma) proteins were screened. Fibrinogen is a large protein which interacts with platelets during blood clotting; it is a good example of a “sticky protein”. Lysozyme is smaller and positively charged under the experimental conditions used, and is often employed as a model protein to study electrostatic adsorption. The experimental protocol for measuring protein adsorption entailed firstly ensuring a clean surface by flowing a 40 mM in phosphate buffered saline solution of sodium dodecyl sulphate (+99%, Sigma) over the surface for 3 min followed by flushing with phosphate buffered saline for 10 min. Next, the protein solution (1 mg ml⁻¹ in phosphate buffered saline, pH 7.4) was passed over the surface for 30 min. Finally, phosphate buffered saline was flushed through the system for 10 min in order to dislodge any loosely-bound proteins. The flow rate for all SPR experiments was set at 10 μl min⁻¹. In all cases, the buffer was de-gassed and filtered using a 200 nm cellulose nitrate filter (Whatman) prior to use.

The films remained protein resistant at body temperature (i.e. 36° C.). In contrast, continuous wave plasma deposition conditions gave rise to approximately two orders of magnitude greater protein adsorption. UV irradiation of the pulsed plasma deposited poly(n-acryloylsarcosine methyl ester) for 40 min was sufficient to change the previously protein-resistant films to being as protein-receptive as the continuous wave film.

With reference to FIG. 5, SPR analysis of the adsorption of the fluorescent marker Alexa-fluor 633 IgG protein independently confirmed the good protein-resistance properties of the pulsed plasma deposited poly(n-acryloylsarcosine methyl ester) films illustrated in FIG. 4.

Alexa-fluor 633 goat anti-mouse immunoglobulin (IgG, 2 mg ml⁻¹ in phosphate buffered saline, Molecular Probes) further diluted to a concentration of 250 μg ml⁻¹ in phosphate buffered saline was employed as a fluorescent marker for mapping patterned arrays of pulsed plasma deposited poly(n-acryloylsarcosine methyl ester) films by fluorescent microscopy. Negative image protein arrays were created by embossing nickel grids (2000 mesh, 7.5 μm holes with 5 μm bars, Agar Scientific) into polystyrene plates using a weight of 4 tons for 10 s, followed by pulsed plasma deposition of poly(n-acryloylsarcosine methyl ester). The nickel grid was then lifted off from the polystyrene substrate to leave behind a well-defined array of plasma polymer. Positive image protein arrays were created by pulsed plasma depositing poly(n-acryloylsarcosine methyl ester) films onto a blank polystyrene chip and then irradiating through a nickel mask (2000 mesh, 7.5 μm holes with 5 μm bars, Agar Scientific) using a wide band HgXe UV source arc-lamp (Oriel model 6136) operating at a power of 0.3 W cm⁻¹ for 40 min. All patterned chips were subsequently immersed into a 250 μg ml⁻¹ solution of Alexa-fluor 633 IgG in phosphate buffered saline for 60 min. This was followed by successive rinses in phosphate buffered saline, 50% phosphate buffered saline diluted with deionized water, and finally twice with deionized water prior to fluorescent microscopy analysis. A Raman microscope system (LABRAM, Jobin Yvon) was used to collect a two-dimensional fluorescent map of the Alexa-fluor 633 IgG protein patterned surfaces. This entailed focusing an unattenuated 633 nm He—Ne laser beam (20 mW) onto the sample using a microscope objective (×50) and the corresponding fluorescence signal collected through the same objective via a back-scattering configuration in combination with a cooled CCD detector. The diffraction grating was set at 300 groves mm⁻¹ with the laser filter at 100% transmission. The sample was mounted onto a computerized X-Y translational mapping stage and the surface rastered (50 μm×50 μm) using a 1 μm step size.

Fluorescence microscopy of the embossed array of pulsed plasma deposited poly(n-acryloylsarcosine methyl ester) following the adsorption of Alexa-fluor 633 IgG protein (negative image) showed clear contrast in signal intensity between the regions of plasma polymer (dark squares) and the uncoated polystyrene (bright grid). Whereas fluorescence microscopy of the UV patterned pulsed plasma deposited poly(n-acryloylsarcosine methyl ester) array after exposure to Alexa-fluor 633 IgG protein (positive image) only displayed signal intensity corresponding to UV exposure (bright squares) and not from the unexposed areas (dark grid).

In summary, proteins in aqueous solution present hydrophilic groups at the protein-water interface, and any of these interfacial functionalities which are charged will attract an electric double layer of ions from the surrounding solution to screen the charge. Along with these counterions a sheath of structured water molecules surrounding the protein will exist. Likewise, a hydrophilic molecule such as protein-resistant PEO, phosphorylcholine, or zwitterionic sulphobetaine will possess a similar surrounding sheath of ordered water molecules, as verified by Raman spectroscopy. These protein-resistant moieties are understood to disrupt the ordering of water molecules in the domain local to a protein significantly less than non-protein-resistant substrates (such as poly(hydroxyethyl methacrylate), sodium poly(ethylenesulfonate), and poly-L-lysine). Thus in the former case, any long-range attractive forces between the protein and the surface are insufficient to overcome the steric repulsion encountered when the structured water interface around the protein and the surface try to overlap, and hence the surface is rendered protein-resistant, i.e. it has an excluded volume. Other factors such as the packing, alignment and flexibility of the surface molecules may also be taken into account to effect the protein resistance.

Pulsed plasma deposited poly(n-acryloylsarcosine methyl ester) is hydrophilic with a contact angle of 44±1.7°, as indicated by Table 1 above. This hydrophilicity stems from the terminal ester group and the polymer backbone amide linkages. Furthermore, the polymer does not contain any groups with hydrogen-bond donating capacity, i.e. it obeys the set of four molecular criteria postulated by Whitesides for protein resistance; these being the presence of (i) polar functional groups, (ii) hydrogen bond accepting groups, (iii) the absence of hydrogen bond donating groups, and (iv) no net charge. Therefore it seems highly probable that the hydrated surface of poly(n-acryloylsarcosine methyl ester) films forms an exclusive volume to proteins that renders it protein-resistant.

Further tests (not shown) have shown that the long-term protein resistance of the poly(n-acryloylsarcosine) surface does not deteriorate over several months. The plasma polymer is not susceptible towards oxidative degradation when placed in either air or phosphate buffered saline solution, thus avoiding the disadvantage associated with PEO films. Furthermore, it benefits in that—unlike poly(n-isopropylacrylamide)—this polymer remains protein-resistant at body temperature (36° C.). In the case of pulsed plasmachemical deposition, the coating is also substrate-independent, giving applicability to diverse uses such as protein-resistant biomaterials and proteomics chips. The coating may be applied to gold, glass, silicon, polystyrene microspheres, and polymer non-wovens. Furthermore, by the application of the coating material onto the substrate through a mask or template so specific domains or areas of the substrate can be defined to have the protein resistant characteristics thus allowing the generation of specific areas in which samples can be applied and held in these specific areas. In one embodiment these specified areas can be further defines by visually apparent grid patterns or other markings which are present on the substrate, perhaps as a result of printing with the markings in register with the said areas of domain.

In a further example of the invention there is provided results which show the use of the invention for Protein adsorption onto locally activated NASME surfaces for better definition Protein Arrays

TABLE 2
Proteins and fluorophores used in this study.

| | | Fluorophore |
|---|---|---|
| Protein | | attached to |
| Label | Protein | protein |
| Probe I | IgG from equine serum, reagent | N/A |
| | grade >= 95%, lypophilized, | |
| | essentially salt-free (Molecular | |
| | Probes Inc) | |
| Probe II | Protein A from staphylococcus | FITC |
| | aureus (Sigma-Aldrich Ltd) | |
| Probe III | Protein G from streptococcus sp, | N/A |
| | lypophilized from a Tris-HCl | |
| | buffer (Sigma-Aldrich Ltd) | |
| Probe IV | Goat antimouse IgG (H + L) | Alexa fluor 633 |
| | 2 mg/L in 0.1M NaP, 0.1M NaCl pH | |
| | 7.5 5 mM azide | |

In experimentation in this case protein immobilization to pulsed plasma polymerised NASME surfaces entailed immersing a protein Probe into a buffer pH=7.5 (consisting of 200 nM sodium hydroxide, 2% Ficoll 400, 2% polyvinylpyrollidone (PVP), 0.5% sodium dodecyl sulphate (SDS) and sodium chloride/sodium citrate (3 M NaCl, 0.3 M Na Citrate—2H₂O, Aldrich)) to a final concentration of 20 μg/mL. The buffered solution was placed onto freshly prepared pulsed plasma poly(NASME) surfaces using a robotic microarrayer (Genetix Inc) equipped with micro-machined pins that consistently delivered samples of ˜1 nL (20 μg/L buffered protein solution) onto the pulsed plasma poly(NASME) coated glass slides (18×18×0.17 mm, BDH) at designated locations. Typical circular spots with diameter ranging from 250-300 μm and with a minimum print pitch of 900 μm could be routinely obtained. After this “spotting” process, the protein immobilised slides were kept in a humidity chamber (64% relative humidity) for 72 hours at 37° C. Finally, the slides were removed and washed with buffer solution and copious amounts of water for a further 72 hours. Probe I, II, III and IV (Table 2) were used in the spotting process. A further microarray pattern was developed consisting of spots of alternating probe I and III.

Protein microarrays of Probe I and III were subsequently exposed to a single complementary protein solution of probe II and probe IV, respectively, dissolved into a phosphate buffered saline solution (pH=7.0 Sigma-Aldrich Ltd) to a final concentration of 20 μg/mL. Two small strips of adhesive tape were affixed along the rim of Probe I and III patterned slides and then covered with a cleaned microscope slide cover glass. The cavity formed between the chip and the cover glass was filled by slowly loading 10 μL of the complementary solution by capillary force. The slide was incubated in a humidified chamber was immersed in at 37° C. for 24 hours. After the cover glass was removed, the chip was washed three times with buffer solution and then with copious amounts of water (48 hours) and blow dried with nitrogen gas.

Fluorescent microscopy mapping was performed using an Olympus IX-70 microscope driven by the SoftWorx package system (DeltaVision RT, Applied Precision). Image data was collected using excitation wavelengths at 525 nm and 633 nm corresponding to the absorption maxima of the dye molecules, FITC and alexa fluor 633 respectively. Imaging was performed using ×10 objective using Openlab software (Improvision). Finally, Images were deconvolved using SoftWorx and quick projections saved as Adobe Photoshop images.

In the case of immobilisation of proteins Probe II and IV, fluorescent images of an array of spots with an average diameter of 250 microns and a print pitch of 900 microns is in accord with the spotting parameters used and images are shown in FIGS. 6(a) and (b). In the case of complementary arrays, a similar pattern was obtained on the surface; however, the spot size had increased to 300 microns in diameter and the spots have an inhomogeneous outer edge density signal as shown in FIGS. 7(a) and (b). Upon exposure of the alternating microarray pattern of probe I and III to probe II only binding to probe I was observed as shown in FIG. 8(a). Additionally, upon exposure of the alternating microarray to probe IV, only binding to probe III was observed, FIG. 8(b).

The benefit of this particular, localised, NASME activation method is that the region surrounding each immobilised protein spot remains protein-resistant, thereby offering superior definition compared to previous methods.

It will be appreciated by persons skilled in the art that the present invention also includes further additional modifications made to the method which does not effect the overall functioning of the method.

1. A method of coating a surface with a material, via one or more application steps, to increase the protein resistance of at least part of the surface, wherein said material is an n-substituted glycine derivative.

2. A method according to claim 1 wherein the n-substituted glycine derivative includes one or more unsaturated polymerizable functional groups.

3. A method according to claim 2 wherein the group is any or any combination of vinyl, styrene, acrylate, methacrylate, acrylamide, and/or the like.

4. A method according to claim 1 wherein the n-substituted glycine derivative includes an acrylamide group.

5. A method according to claim 1 wherein the n-substituted glycine derivative is a methyl ester of glycine.

6. A method according to claim 1 wherein the n-substituted glycine derivative is or includes n-acryloylsarcosine methyl ester.

7. A method according to claim 1 wherein the material is provided in a patterned manner on the surface areas or domain with increased pattern resistance in comparison to other areas of the substrate surface.

8. A method according to claim 1 wherein the n-substituted glycine derivative is any or any combination of n-methyl-n-2-propenyl methyl ester, acryloylsarcosine methyl ester, N-methoxyethylglycine oligomers, sarcosine-based monomers, and/or other n-substituted glycine derivatives.

9. A method according to claim 1 wherein the n-substituted glycine derivative is polymerized in combination with other polymerizable monomers to form n-substituted glycine copolymers.

10. A method according to claim 9 wherein monomers for copolymerization include any or any combination of vinyls, styrenes, acrylates, acrylamides, and/or the like.

11. A method according to claim 1 wherein the method includes pulsed plasmachemical deposition of the material.

12. A method according to claim 1 wherein the method includes low-power continuous-wave plasma deposition of the material.

13. A method according to claim 11 wherein pulsed plasmachemical deposition constitutes the generation of active sites at the surface and in the electrical discharge during a duty cycle on-period, followed by polymerization reaction pathways proceeding during an extinction period.

14. A method according to claim 13 wherein the active sites are predominantly radicals.

15. A method according to claim 13 wherein the duty cycle on-period lasts between 1-100 microseconds and the extinction period lasts between 1-20 milliseconds.

16. A method according to claim 1 wherein the application steps are solventless and/or substrate independent.

17. A method according to claim 1 wherein the application steps include any or any combination of grafting by pre-irradiation of a surface with ionizing radiation or plasma, grafting by surface polymerization from an initiator layer, by free radical polymerization, atom transfer free radical polymerization, iniferter polymerization, ionic polymerization, and/or photopolymerization.

18. A method according to claim 1 wherein the application steps include any or any combination of surface physisorption or chemisorption of pre-formed n-substituted glycine derivative oligomers or polymers onto a solid surface.

19. A method according to claim 11 or 12 wherein the plasma operates at low, sub-atmospheric or atmospheric pressure.

20. A method according to claim 19 wherein the n-substituted glycine derivative is introduced into the plasma as a vapour or an atomised spray of liquid droplets.

21. A method according to claim 19 wherein the monomer is introduced into the plasma deposition apparatus continuously, or in a pulsed manner.

22. A method according to claim 1 wherein a substrate to which the protein resistant coating is applied is located substantially inside a pulsed plasma during coating deposition.

23. A method according to claim 1 wherein the substrate is located outside of a pulsed plasma.

24. A method according to claim 1 wherein the n-substituted glycine derivative is directly excited within a plasma discharge.

25. A method according to claim 1 wherein a remote plasma deposition methods is used, wherein the material enters the deposition apparatus substantially downstream of the pulsed plasma.

26. A method according to claim 11 or 12 wherein the plasma comprises the n-substituted glycine derivative alone, substantially in the absence of other compounds.

27. A method according to claim 26 wherein plasmas consisting of n-substituted glycine derivative alone are achieved by first evacuating the reactor vessel as far as possible, purging the reactor vessel with the n-substituted glycine derivative for a period of time sufficient to ensure that the vessel is substantially free of other gases.

28. A method according to claim 27 wherein the temperature in the plasma chamber is sufficiently high to allow sufficient material monomer in gaseous phase to enter the plasma chamber.

29. A method according to claims 1 or 12 wherein materials additional to the n-substituted glycine derivative are present within the plasma.

30. A method according to claim 29 wherein said additive materials are inert and act as buffers without any of their atomic structure being incorporated into the growing plasma polymer.

31. A method according to claim 30 wherein said additive materials are noble gases.

32. A method according to claim 29 wherein the additive materials include other monomers so that the resultant coating formed on the substrate is a copolymer.

33. A method according to claim 32 wherein monomers for use within the method of the invention include organic, inorganic, organo-silicon and organo-metallic monomers.

34. A method according to claim 1 wherein the method is employed for use in bio-micro electromechanical systems and for coating other biomaterial surfaces where an immune response is not desired.

35. A method according to claim 1 wherein said method includes the step of applying the material using a pulsed plasmachemical deposition technique.

36. A method according to claim 35 wherein the material is an n-substituted glycine derivative.

37. A method according to claim 1 wherein the increased protein resistant surface is only provided at selected surface areas or domains on the substrate surface.

38. A method according to claim 37 wherein the selection is achieved by plasma depositing the coating through a mask or template to produce a substrate surface, with the domains or areas covered with protein resistant material juxtaposed with areas of the substrate that have no protein resistant material applied thereto.

39. A method according to claim 37 wherein the steps include depositing the material over the entire surface of the substrate and then rendering selected areas of the surface incapable of protein resistance.

40. A method according to claim 37 wherein the material restricted to specific surface domains is an n-substituted glycine derivative.

41. A method according to claim 37 wherein the areas provided with the protein resistant areas or domains are provided in register with visually apparent markings, on the substrate.

42. A method of applying a material to a substrate, via one or more application steps, to increase the protein resistance of the surface, wherein said material which is applied is a poly(n-acryloylsarcosine methyl ester).

43. A method according to claim 37 wherein the method results in a product wholly coated in a protein resistant polymer coating.

44. A substrate having an outer surface formed at least partially of an n-substituted glycine derivative applied in accordance with the method of claim 1.

45. A substrate according to claim 44 wherein the substrate has a layer of n-substituted glycine derivative applied thereto to form an outer surface thereof.

46. canceled.

47. A substrate according to claim 44 wherein the substrate includes a protein resistant is formed of any or any combination of woven or non-woven fibres, natural fibres, synthetic fibres, metal, glass, ceramics, semiconductors, cellulosic materials, paper, wood, or polymers such as polytetrafluoroethylene, polythene or polystyrene.

48. (canceled)

49. (canceled)
